(19) United States
(12) Patent Application Publication
(10) Pub. No.: US 2015/0279791 A1
(43) Pub. Date: Oct. 1, 2015

(54) SEMICONDUCTOR DEVICE

(71) Applicant: KABUSHIKI KAISHA TOSHIBA, Minato-ku (JP)

(72) Inventor: Keiju YAMADA, Yokohama (JP)

(73) Assignee: KABUSHIKI KAISHA TOSHIBA, Minato-ku (JP)

(21) Appl. No.: 14/618,328

(22) Filed: Feb. 10, 2015

(30) Foreign Application Priority Data
Mar. 28, 2014 (JP) 2014-069173

(51) Int. Cl. H01L 23/66; H01L 23/64; H01L 23/498

(52) U.S. Cl. CPC H01L 23/66; H01L 23/49838; H01L 23/49816; H01L 23/645

(57) ABSTRACT

According to one embodiment, a semiconductor device includes a part or entirety of a switching power supply, at least one semiconductor element, and at least one line composed of a inner conductor and a soft magnetic member sheathing the inner conductor. The semiconductor device further includes, for example, a circuit substrate on which the part or entirety of the switching power supply and the semiconductor elements are mounted. The lines are mounted on the circuit substrate.

### CROSS-REFERENCE TO RELATED APPLICATIONS

This application is based upon and claims the benefit of priority from Japanese Patent Application No. 2014-069173, filed Mar. 28, 2014; the entire contents of which are incorporated herein by reference.

### FIELD

Embodiments described herein relate generally to semiconductor device.

### BACKGROUND

Mobile communication apparatuses, such as mobile telephones, tablet terminals and notebook-type personal computers (notebook PCs), have a switching power supply configured to turn on and off the semiconductor elements. The switching power supply must be small enough to be incorporated in, for example, a semiconductor package. It is demanded that a high-speed switching power supply having a switching frequency of MHz band should be provided as such a small switching power supply.

As such a switching power supply, a boost converter having an inductor is used. The boost converter can output a large current with high power efficiency, can respond at high speed and can be small enough to be incorporated into a semiconductor package.

### BRIEF DESCRIPTION OF THE DRAWINGS

FIG. 1 is a sectional view showing a semiconductor package that is a semiconductor device according to an embodiment;

FIG. 2 is a bottom view showing the parts of the semiconductor device, such as solder balls and lines used as connection terminals of the semiconductor package, and also the lower surface (bottom) of an interposer;

FIG. 3 is a structural view showing a line sheathed with soft magnetic material and incorporated in the semiconductor package;

FIG. 4A is a diagram showing a cross sectional shape that the inner conductor of each magnetic sheathed wire may have in the semiconductor package;

FIG. 4B is a diagram showing a different cross sectional shape that the inner conductor of each magnetic sheathed wire may have in the semiconductor package;

FIG. 5 is a diagram showing an exemplary method of producing the magnetic sheathed wires in the semiconductor package;

FIG. 6 is a diagram showing an exemplary method of producing the semiconductor package;

FIG. 7 is a diagram showing the relative permeability that the lines made of CoNbZr have with respect to the frequency in the semiconductor package;

FIG. 8 is a diagram showing the result of analyzing the frequency characteristic of the inductance of a air-core inductor and that of the inductance of each magnetic sheathed wire;

FIG. 9 is a diagram showing the frequency characteristic of Ploss/Pin, i.e., index of the noise control performed by the air-core inductor and the magnetic sheathed wires; and

FIG. 10 is a table showing the result of electromagnetic-field analysis of the rate at which the inductance at a frequency of 20 MHz changes in accordance with the pattern of the interposer.

### DETAILED DESCRIPTION

In general, according to one embodiment, a semiconductor device includes a part or entirety of a switching power supply, at least one semiconductor element, and at least one line composed of a inner conductor and a soft magnetic member sheathing the inner conductor.

An embodiment will be described with reference to the accompanying drawings.

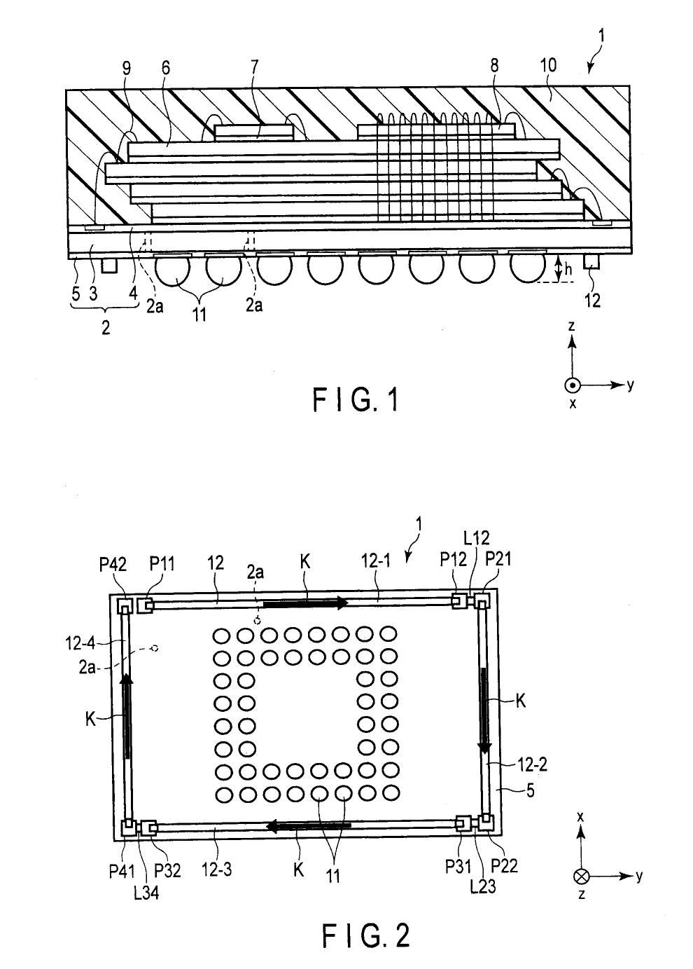

FIG. 1 is a sectional view of a semiconductor device, namely a semiconductor package 1. The semiconductor package 1 includes an interposer 2 on which a plurality of lines are formed. The interposer 2 is shaped like, for example, a rectangular flat plate. The interposer 2 includes an insulating base 3, a first wire layer 4, and a second wire layer 5. The insulating base 3 is made of an insulator. The first wire layer 4 is formed on the upper surface of the insulating base 3. The second wire layer 5 is formed on the lower surface (bottom) of the insulating base 3. On the first wire layer 4, a plurality lines are formed. On the second wire layer 5, too, a plurality wiring are formed. In this embodiment, the interposer 2 includes two wire layers. However, the number of wire layers is not limited to two. Three or more wire layers may be provided in the interposer 2.

On the upper surface of the first wire layer 4 formed on the interposer 2, one or more semiconductor elements 6 are mounted. In the semiconductor package 1 of FIG. 1, a plurality of semiconductor elements 6 are provided. On the uppermost of these semiconductor elements 6, the switching element 7 and semiconductor element 8 of a switching power supply are mounted. The semiconductor element 6 and the semiconductor element 8 differ in function from each other. The switching element 7 is not always provided on the upper surface of the semiconductor elements 6, and may be provided on either the upper or lower surface of the interposer 2. A plurality of wires 9 connect the switching element 7, semiconductor element 8 and first wire layer 4 to one another. The switching element 7, semiconductor element 8 and first wire layer 4 are electrically connected by the wires 9. The interposer 2 has a plurality of through holes 2a, each extending from the upper surface of the interposer 2 to the lower surface thereof. Each through hole 2a serves to connect the first wire layer 4 and the second wire layer 5 electrically. The first wire layer 4 formed on the upper surface of the interposer 2, the semiconductor elements 6, the switching element 7, the semiconductor element 8 and the wires 9 are sealed in a resin layer (hereinafter referred to as sealing resin layer 10). The semiconductor device according to the embodiment is therefore packaged (thus providing a semiconductor package 1).

FIG. 2 shows solder balls 11 and lines 12 mounted on the lower surface of the interposer 2. The solder balls 11 are provided on the upper surface of the second wire layer 5 formed on the lower surface of the interposer 2. Each solder ball 11 is a external terminal of the the semiconductor package 1 The solder balls 11 have a height h of, for example, 0.25 mm, measured from the upper surface of the second wire layer 5.

The lines 12 serve as inductors of a boost converter that constitutes the switching power supply. Each line 12 is composed of a inner conductor 20 and a magnetic sheath covering the inner conductor 20. Therefore, the lines 12 shall hereinafter be called “magnetic sheathed wires 12.” The magnetic sheathed wires 12 are mounted on the lower surface of the interposer 2, which faces away from the upper surface on which the semiconductor elements 6 are mounted. The magnetic sheathed wires 12 have a thickness smaller than the diameter of the solder balls 11.

As shown in FIG. 2, the magnetic sheathed wires 12 are mounted, extending along the sides of the interposer 2. More precisely, as FIG. 2 shows, the magnetic sheathed wires 12 are, for example, four magnetic sheathed wires 12-1 to 12-4 provided on the lower surface of the rectangular interposer 2 and extend along the straight four sides thereof. The magnetic sheathed wires 12 may be mounted on the upper surface of the interposer 2, not on the lower surface thereof.

At the four corners of the interposer 2, eight electrodes are provided, respectively. Electrode P12 and electrode P21 are connected by a line L12, electrode P22 and electrode P31 are connected by a line L23, and electrode P32 and electrode P41 are connected by a line L34.

The four magnetic sheathed wires 12-1 to 12-4 are connected, respectively, to the electrodes P11 and P12 forming a pair, the electrodes P21 and P22 constituting a pair, the electrodes P31 and P32 constituting a pair, and the electrodes P14 and P42 constituting a pair. The magnetic sheathed wire 12-1 is connected, at one end, to the electrode P11, and at the other end, to the electrode P12. The magnetic sheathed wire 12-2 is connected, at one end, to the electrode P21, and at the other end, to the electrode P22. The magnetic sheathed wire 12-3 is connected, at one end, to the electrode P31, and at the other end, to the electrode P32. The magnetic sheathed wire 12-4 is connected, at one end, to the electrode P41, and at the other end, to the electrode P42. The four magnetic sheathed wires 12-1 to 12-4 are thereby electrically connected in series to one another by the electrodes P11, P12, P21, P22, . . . P42.

The magnetic sheathed wires 12-1 to 12-4 are mounted, extending along the straight four sides thereof, respectively. The magnetic sheathed wires 12-1 to 12-4 therefore form one turn of a coil. The one-turn coil composed of the magnetic sheathed wires 12-1 to 12-4 functions as the inductor of a boost converter for constituting a switching power supply. The magnetic sheathed wires 12 may form not only a one-turn coil, but also a coil of two or more turns, if more magnetic sheathed wires are mounted, extending along each side of the interposer 2.

the magnetic sheathed wires 12-1 to 12-4 are induced easy axis of magnetic anisotropy in the direction K in FIG. 2 to enhance inductance of the coil.

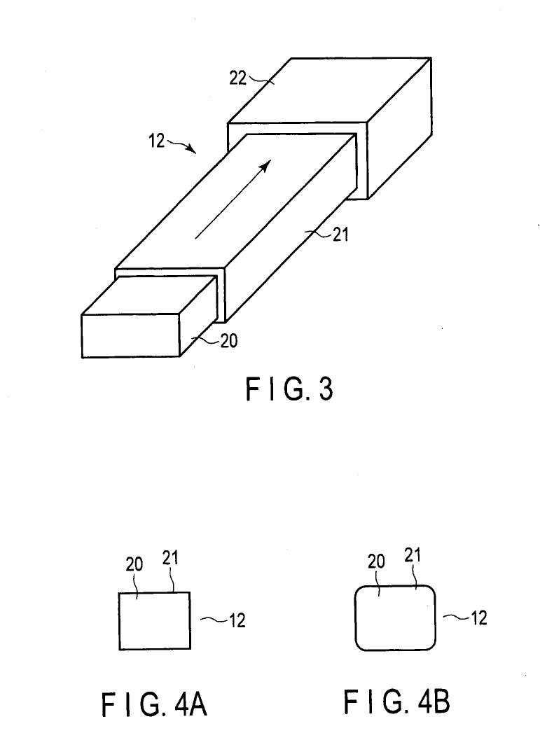

FIG. 3 is a structural view showing a magnetic sheathed wire 12. The magnetic sheathed wire 12 includes a inner conductor 20 and a magnetic layer covering the inner conductor magnetic layer an insulating layer 22. magnetic layer magnetic layer

The inner conductor 20 is preferably be made of a material of high conductivity to have low electric resistance. Materials having high permeability are, for example, Cu, Ag, Au and Al.

The magnetic layer 21 is made up of soft magnetic material, which is electrically conductive. The electrically conductive, soft magnetic material is, for example, CoNbZr, CoFbB, CoZrO, CoAlO, or NiFe. More precisely, the magnetic layer 21 composed of uniaxial anisotropy in the longitudinal direction of the magnetic sheathed wire 12. The magnetic layer 21 is made of, for example, Co85Nb12Zr3, which has a relative permeability of 1000 in the direction of the hard axis of the magnetic-anixotropy.

In each of the magnetic sheathed wires 12-1 to 12-4, the magnetic layer 21 is covered with the insulating layer 22 in most cases, in order to prevent short-circuiting between the magnetic sheathed wire 12 and any other line. The material of the insulating layer 22 is, for example, polyamide.

Assume that the magnetic layer 21 has thickness tm, the switching frequency of the power in the semiconductor package 1 is switching frequency f1, the high-frequency current flowing in the skin part of the magnetic layer 21 has skin depth δ, the thickness tm of the magnetic layer 21 is equal to the skin depth δ of the magnetic layer 21 at frequency f2 (hereinafter called equal-thickness frequency), and the material of the magnetic layer 21 has ferromagnetic resonance frequency f3.

The thickness tm of the magnetic layer 21 is smaller than the skin depth δ of the magnetic layer 21 at switching frequency f1.

The thickness tm of the magnetic layer 21 is larger than the skin depth δ of the magnetic layer 21 at the ferromagnetic resonance frequency f3 of the material of the magnetic layer 21.

The magnetic layer 21 has thickness tm for a specific reason. That is, in the magnetic layer 21, the current flows in the skin part at the depth δ. The skin depth δ is greater than the thickness tm of the magnetic layer 21 if the current has a low-band frequency, and is smaller than the thickness tm of the magnetic layer 21 if the current has a high-band frequency. The skin depth δ (=tm) has a value at the low-band frequency, and a different value at the high-band frequency.

The skin depth δ in the magnetic layer 21 is given as follows:

$$δ = \sqrt{\frac{1}{π f σ {μ}_{0} {μ}_{r}}}$$

$${μ}_{r} = {μ}_{r}^{′} - j {μ}_{r}^{″}$$

where f is the frequency, σ is the conductivity of the soft magnetic material, μ0 is the permeability in vacuum, μr is the relative complex permeability of the soft magnetic material, μr′ is the real-part value of the relative complex permeability of the soft magnetic material, and μr″ is the imaginary-part value of the relative complex permeability of the soft magnetic material. Permeability μr, permeability μr′ and permeability μr″ have frequency characteristic.

At any frequency much lower than frequency f2 at which the thickness tm of the magnetic layer 21 is equal to the skin depth δ at which current flows in the magnetic layer 21, the current flows in the inner conductor 20 that has high conductivity. Therefore, the magnetic sheathed wire 12 has low resistance. In this frequency band, the magnetic sheathed wire 12 has an inductance per unit length higher than in the case where the magnetic layer 21 is not arranged.

Hence, the switching frequency f1 of the power circuit is set lower than the frequency f2. The frequency to transmit signals or power, for example, are set lower than the frequency f2.

In a frequency band higher than the frequency f2 the current flows mainly in the magnetic layer 21 that has relatively low conductivity. The resistance of the magnetic sheathed wire 12 therefore is high at higher frequency than the frequency f2.

Further, the imaginary-part value pr″ of the relative complex permeability of the magnetic layer 21 increases to a maximum at the ferromagnetic resonance frequency f3 of the material of the magnetic layer 21. The absolute value of the relative complex permeability μr of the magnetic layer 21 therefor increases to a maximum, too.

As a result, at the frequency f3, the magnetic layer 21 has the minimal skin depth δ and, hence, has very high resistance and a high transmission loss.

Assume that the switching frequency f1 of the switching power supply is set to, for example, 20 MHz in order to control noise at 300 MHz or more. Based on this assumption, magnetic sheathed wire 12 is used. Then, each magnetic sheathed wire 12 should be a inner conductor 20 sheathed with Co85Nb12Zr3 having a relative permeability of 1000 in the direction of the uniaxial magnetic-anisotropy hard axis.

Co85Nb12Zr3 has a conductivity of 8.3×10 S/m and ferromagnetic resonance frequency f3 of 890 MHz.

The frequency f2 at which the thickness tm of the magnetic layer 21 is equal to the skin depth δ of the CoNbZr layer may be set to 300 MHz. Then, the skin depth δ of the CoNbZr layer is 1.0 μm at this frequency f2 (=300 MHz). Hence, the CoNbZr layer may be 1.0 μm thick, too.

The soft magnetic material forming the magnetic layer 21 exhibits uniaxial anisotropy. The soft magnetic material acquires high permeability if magnetic field is applied in the direction of the hard axis.

If the magnetic-anisotropy easy axis is induced to the longitudinal direction of the magnetic sheathed wire 12, the magnetic sheathed wire 12 shown in FIG. 3 will become a line that has high inductance and a low loss at any frequency lower than the switching frequency f1 of the switching power supply. The uniaxial anisotropy is induced in the soft magnetic material by performing a heat treatment on the material in a magnetic field and then cooling the material also in the magnetic field.

As shown in FIG. 2, each magnetic sheathed wire 12 is mounted on the surface of the interposer 2. The magnetic sheathed wire 12 is mounted on the surface of the Interposer 2 after the uniaxial anisotropy has been induced in the soft magnetic material. Thus, the magnetic-anisotropy easy axis is set in each magnetic sheathed wire 12, in the longitudinal direction thereof.

As a result, the relative permeability of the soft magnetic material of each magnetic sheathed wire 12 can be enhanced, imparting high inductance to the magnetic sheathed wire 12. The relative permeability cannot be enhanced in all directions if the anisotropy is induced in the heat treatment after mounting the magnetic sheathed wire 12 on the surface of the interposer 2.

Each magnetic sheathed wire 12, more precisely the inner conductor 20 thereof, has a polygonal cross section as shown in FIG. 4A or a polygonal cross section with rounded corners, as shown in FIG. 4B.

Having such a cross section, the magnetic sheathed wire 12 will not roll on the interposer 2 as it is mounted at a designated position on the surface of the interposer 2.

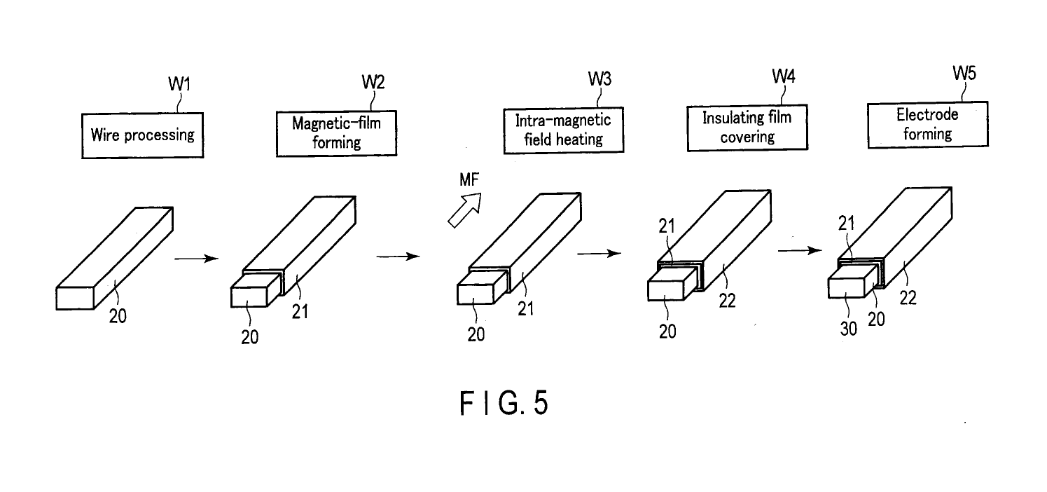

An exemplary method of producing the magnetic sheathed wires 12 will be described with reference to FIG. 5.

A wire of Cu, for example, is processed in wire-processing step W1. A inner conductor 20 is thereby produced.

A thin film of soft magnetic material is formed, covering the circumferential surface of the inner conductor 20 in magnetic-film forming step W2. A magnetic layer 21 is thereby formed. The magnetic layer 21 may be formed by means of sputtering, electrolytic plating, non-electrolytic plating or vapor deposition.

In an intra-magnetic field heating step W3, a heat treatment is performed on the inner conductor 20 sheathed with a thin soft magnetic film, while applying a magnetic field MF to the inner conductor 20. Uniaxial anisotropy is thereby induced in the inner conductor 20. The heat treatment need not be performed if the soft magnetic material can acquire uniaxial anisotropy during depositing the magnetic layer 21.

In an insulating film covering step W4, an insulating layer 22 is formed on the circumferential surface of the inner conductor 20. The inner conductor 20 is thereby insulated from any other conductor.

An electrode forming step W5 is performed. That is, an Sn film 30 is plated on the inner conductor 20.

The magnetic sheathed wires 12 are thereby produced.

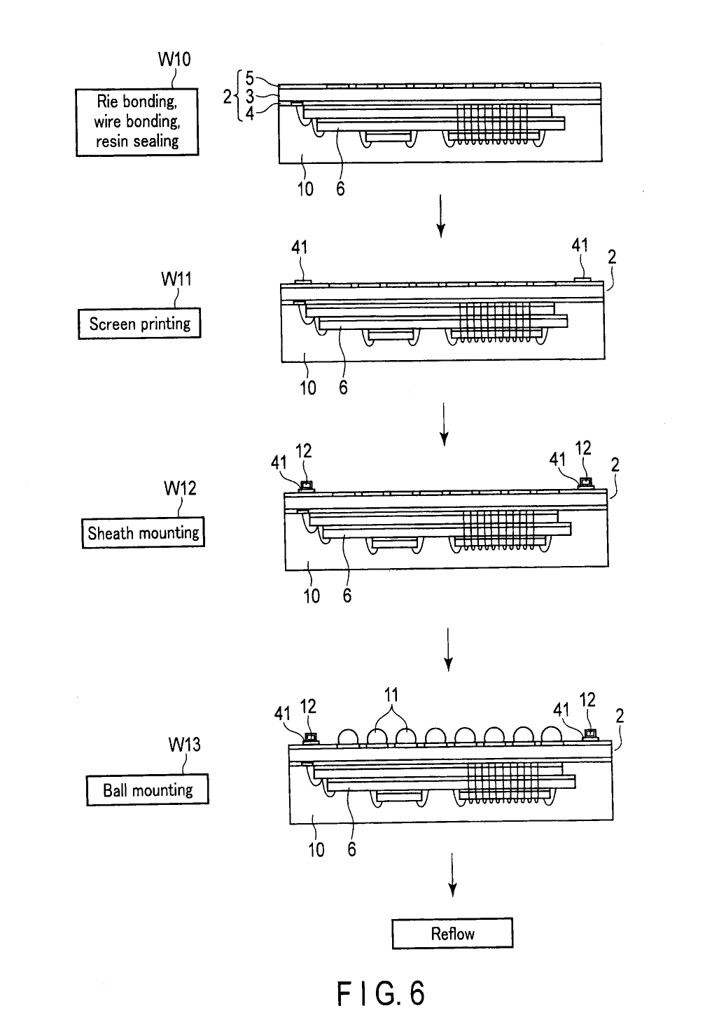

An exemplary method of producing the semiconductor package (semiconductor device) 1 will be described with reference to FIG. 6.

A die bonding, wire bonding and resin sealing step W10 is performed in the same way as in manufacturing the ordinary fine-pitch, ball grid array (FBGA) package. On the upper surface of the interposer 2, a first wire layer 4, semiconductor elements 6, a switching element 7, a controller 8 and the wires 9 are formed and are sealed in sealing resin layer 10.

A screen printing step W11 is performed, screen-printing solder paste layers 41 on the electrodes mounted on the magnetic sheathed wires 12.

A sheathed wire mounting step W12 is performed, mounting the magnetic sheathed wires 12 on the lower surface of the interposer 2. Alternatively, the magnetic sheathed wires 12 may be mounted on the upper of the interposer 2.

In a ball mounting step W13, solder balls 11 are mounted on the lower surface of the interposer 2.

Thereafter, a reflow step is performed, whereby the magnetic sheathed wires 12 are mounted, together with the solder balls 11.

As shown in FIG. 1, FIG. 2 and FIG. 6, the magnetic sheathed wires 12 are mounted on the lower surface of the interposer 2, on which the solder balls 11 are also mounted. Alternatively, the magnetic sheathed wires 12 may be mounted on the upper surface of the interposer 2, on which the semiconductor elements 6 are mounted and sealed in the resin layer 10.

An electromagnetic-field analysis is performed to determine the performance of the magnetic sheathed wires 12 mounted on the semiconductor package 1, as will be explained below.

In the model of the electromagnetic-field analysis, the semiconductor package 1 is, for example, 11.5 mm long in the x direction and 13.0 mm long in the y direction, the interposer 2 is 0.15 mm thick (in z direction), and the sealing resin layer 10 is 0.60 mm thick (in z direction).

In the model, the magnetic sheathed wires 12 extending in the x direction are 10.5 mm long, the magnetic sheathed wires 12 extending in the y direction are 12.0 mm long, and the inner conductor 20 of each magnetic sheathed wire 12 is 0.10 mm thick.

The electromagnetic-field analysis was performed on two models. One model comprises a air-core inductor composed of a magnetic layer 21 without any sheathing. The other model comprises an inductor composed of a magnetic layer 21.

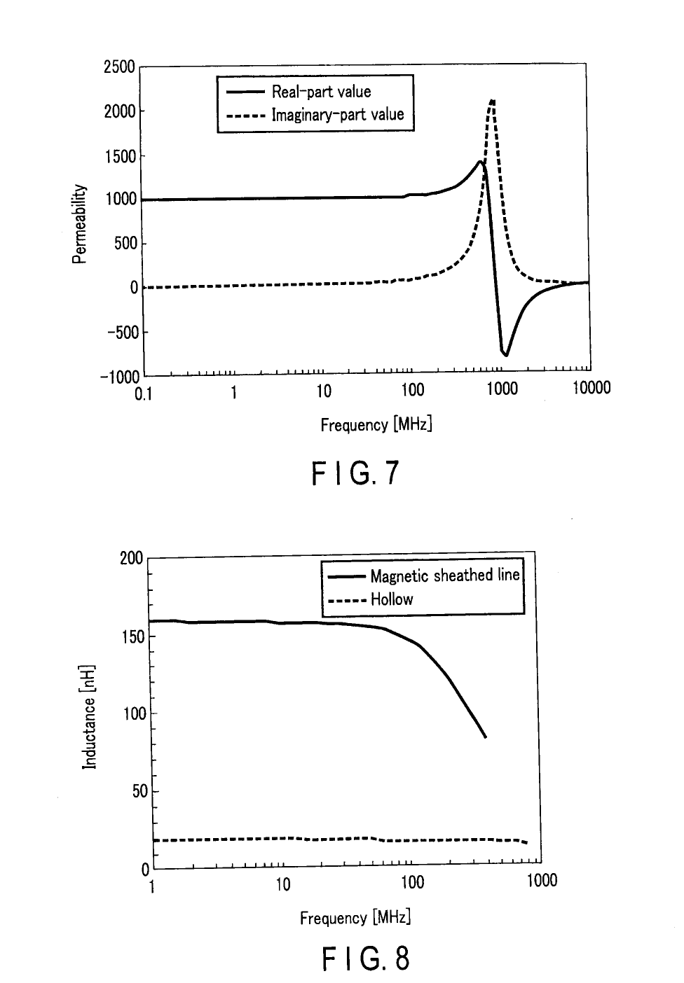

In the inductor composed of each magnetic sheathed wires 12, the magnetic layer 21 is 1.0 m thick and is made of CoNbZr. The relative complex permeability μr of CoNbZr was input the model. The frequency property of the relative complex permeability μr of CoNbZr is shown in FIG. 7.

The permeability of the magnetic layer 21 is based on the assumption that easy axis of uniaxial anisotropy has been induced in the longitudinal direction of the magnetic sheathed wire 12. The magnetic sheathed wires 12-2 and 12-4, which extend in the x direction, were set to a permeability of:

(μx, μy, μz)=(1, μr, μr),

The magnetic sheathed wires 12-1 and 12-3, which extend in the y direction, were set to a permeability of:

(μx, μy, μz)=(μr, 1, μr).

In these equations, μx is the permeability in the x direction, μy is the permeability in the y direction, and μz is the permeability in the z direction.

FIG. 8 shows the result of analyzing the frequency characteristic of the inductance of a air-core inductor and that of the inductance of the inductor composed of magnetic sheathed wires 12. At a frequency of 20 MHz, the inductance of the air-core inductor is 17.7 nH, and the inductance of the magnetic sheathed wire 12 is 155 nH. The inductance of the magnetic sheathed wire 12 is thus 8.7 times as high as that of the air-core inductor.

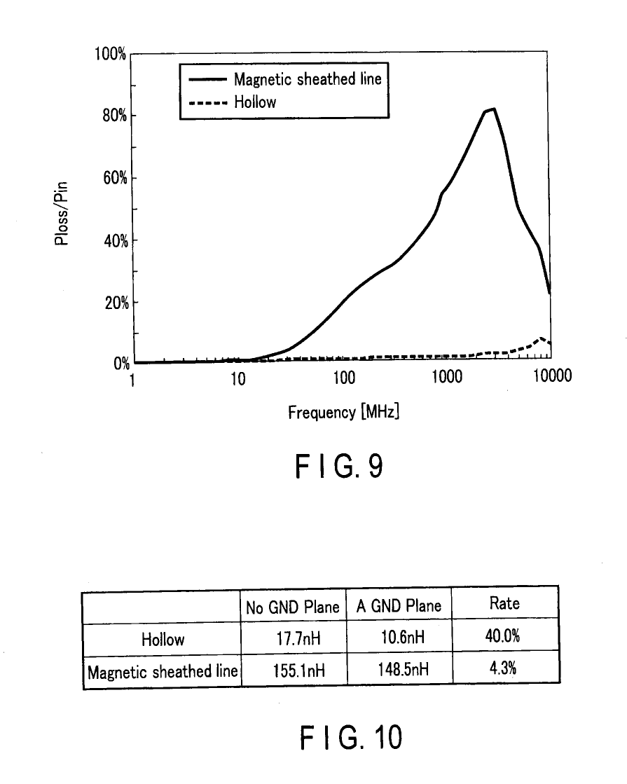

FIG. 9 shows the frequency characteristic of P loss/P in, which is the index of the noise control performed by the air-core inductor and the magnetic sheathed wires 12. In the inductance of the air-core inductor, P loss/P in at a frequency of 1.0 GHz is 1.2%. In the inductor of the magnetic sheathed wire 12, P loss/P in at a frequency of 1.0 GHz is 55.1%. That is, in the inductor of the magnetic sheathed wire 12, a P loss/P greater by 30% or more can be acquired at a frequency of 0.30 GHz to 8.0 GHz.

Hence, the magnetic sheathed wires 12 can suppress noise than the air-core inductor at the wireless frequency band used in, for example, mobile telephone systems.

The influence of the grounding pattern of the interposer 2 was analyzed, as will be described below.

In the analysis, the changes in the inductance of the air-core inductor and the inductor of the magnetic sheathed wire 12 at the frequency of 20 MHz, observed in the case where the interposer 2 has a GND plane, were compared with the changes observed in the case where the interposer 2 has no GND plane.

FIG. 10 shows the result of electromagnetic-field analysis of the rate at which the inductance at frequency of 20 MHz changed in accordance with the pattern of the interposer 2. The inductance of the air-core inductor greatly changed, by 40.0%. The inductance of the magnetic sheathed wire 12 changed a little, by 4.3%. This proves that the inductance of the inductor composed of the magnetic sheathed wire 12 is less influenced than the inductance of the air-core inductor by the pattern of the interposer 2.

The semiconductor package 1 has a switching power supply such as a boost converter. Nonetheless, the semiconductor package 1 can be applied to an inductor for use in impedance matching for signals or to a power supply of the kHz-band frequency.

In the embodiment described above, the magnetic sheathed wires 12, each of which is composed of the inner conductor 20 and the magnetic layer 21 sheathing the inner conductor 20, are mounted on the circuit substrate 2 of the semiconductor package 1 incorporating the switching power supply. The inductors of the switching power supply, which are constituted by the magnetic sheathed wires 12, respectively, can therefore be short length of coil, and the area that the magnetic sheathed wires 12 occupy on the interposer 2 can be small.

Since the magnetic sheathed wires 12 are mounted on the interposer 2 of the semiconductor package 1, the inductor pattern need not be formed on the interposer 2. This helps to reduce the number of layers constituting the interposer 2.

The inductor composed of the magnetic sheathed wires 12 has an inductance of 155 nH as shown in FIG. 8. The inductance can be, for example, 8.7 times as high as that (i.e., 17.7 nH) of the air-core inductor.

Since each magnetic sheathed wire 12 induces a magnetic-anisotropy easy axis in its longitudinal direction, it can have high inductance and can reduce the loss, at any frequency lower than the switching frequency f1 of the switching power supply. Moreover, the magnetic layer 21 can have a high relative permeability, and the magnetic sheathed wire 12 can therefore acquire a high inductance.

The inductor composed of the magnetic sheathed wire 12, which is composed of the inner conductor 20 and the magnetic layer 21 sheathing the inner conductor 20, can suppress the noise than such a air-core inductor as shown in FIG. 9. Hence, the magnetic sheathed wire 12 can greatly suppress the noise at the wireless frequency band used in, for example, mobile telephone systems. That is, if the frequency f is low, the current will flow in the inner conductor 20 that has high conductivity. This enables the magnetic sheathed wire 12, and the loss of the magnetic sheathed wire 12 is almost equal to the loss only in the inner conductor 20.

If the frequency is high, the current will flow, because of the skin effect, to the magnetic layer 21 that has low conductivity. The skin effect and the ferromagnetic resonance therefore result in a large loss. This can suppress the high frequency conductive noise on the magnetic sheathed wire 12.

In comparison with the air-core inductor, the inductor composed of the magnetic sheathed wire 12 undergoes a smaller inductance change due to the pattern of the interposer 2 than the air-core inductor, as seen from FIG. 10 that shows the result of the analysis of the influence imposed by the wiring pattern of the interposer 2.

The magnetic sheathed wire 12 may form not only a one-turn coil, but also a coil having two or more turns. The semiconductor package 1 can therefore change the inductance of the boost converter constituting the switching power supply.

As shown in FIG. 4A and FIG. 4B, the magnetic sheathed wire 12 has a polygonal cross section as shown in FIG. 4A or a polygonal cross section with rounded corners, as shown in FIG. 4B. Having such a cross section, the magnetic sheathed wire 12 will not roll on the interposer 2 as it is mounted at a designated position on the surface of the interposer 2.

The embodiment described above is an FBGA package. The package is not limited to an FBGA package, nevertheless. The invention can be applied to an LGA or a package having leads.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a part or entirety of a switching power supply, at least one semiconductor element, and at least one line composed of a inner conductor and a soft magnetic layer sheathing the inner conductor.

2. The semiconductor device according to claim 1, further comprising;
a circuit substrate on which the part or entirety of the switching power supply and the semiconductor element are mounted,
wherein the line is mounted on the circuit substrate.

3. The semiconductor device according to claim 1, further comprising;
magnetic layer composed of the soft magnetic material sheathing one inner conductor,
wherein the magnetic layer are thinner than the skin part of the soft magnetic member, in which a current flows if the switching frequency of the switching power supply is a fundamental frequency.

4. The semiconductor device according to claim 3, wherein;
the switching frequency of the power circuit is set to a value lower than the frequency at which the skin depth of the magnetic layer is equal to the thickness of the magnetic layer.

5. The semiconductor device according to claim 1, further comprising:
magnetic layer composed of the soft magnetic material sheathing one inner conductor,
wherein the magnetic layer is thicker than the skin depth of magnetic layer at the ferromagnetic resonance frequency of the magnetic layer.

6. The semiconductor device according to claim 2, wherein:
the semiconductor package includes an interposer, the semiconductor element and solder ball serving as terminals of the interposer are mounted on the interposer;
the semiconductor element is sealed in sealing resin;
the wire thinner than thickness corresponding to the diameter of the solder ball;
the wire is mounted on that surface of the interposer which is opposite to the surface on which the semiconductor element is mounted.

7. The semiconductor device according to claim 1, wherein;
easy axis of uniaxial anisotropy is induced in the soft magnetic layer in the longitudinal direction of the line.

8. The semiconductor device according to claim 7, wherein;
at least two lines are mounted on the surface of the interposer and are electrically connected by wires formed on the interposer.

9. The semiconductor device according to claim 8, wherein;
easy axis of uniaxial anisotropy is induced in at least two lines, in the longitudinal direction of the line thereof.

10. The semiconductor device according to claim 9, wherein;
the two lines are arranged, forming a coil having at least one turn.

11. The semiconductor device according to claim 9, wherein:
the at least two lines are mounted, extending along the sides of the circuit substrate.

12. The semiconductor device according to claim 9, wherein:
the inner conductor includes a polygonal cross section or a polygonal cross section with rounded corners.

13. The semiconductor device according to claim 6, wherein:
the interposer includes an insulating base, a first wire layer formed on the upper surface of the insulating base, and a second wire layer formed on the lower surface of the insulating base and composed of a plurality of lines;
the insulating base has through holes, each extending from the upper surface of the insulating base to the lower surface thereof;
the switching power supply is a boost converter, and
the lines constitute the inductor of the boost converter.

14. The semiconductor device according to claim 1, wherein;
the line has been provided by forming, on the inner conductor, a film of amorphous material of the soft magnetic member.
